(19) United States
(12) Patent Application Publication
(10) Pub. No.: US 2013/0287969 A1
(43) Pub. Date: Oct. 31, 2013

(54) METHOD FOR DEPOSITING A TRANSPARENT BARRIER LAYER SYSTEM

(71) Applicants: Steffen Guenther, Dresden (DE); Bjoern Meyer, Dresden (DE); Steffen Straach, Dresden (DE); Thomas Kuehnel, Pirna (DE); Sebastian Bunk, Dresden (DE); Nicolas Schiller, Stolpen OT Helmsdorf (DE)

(72) Inventors: Steffen Guenther, Dresden (DE); Bjoern Meyer, Dresden (DE); Steffen Straach, Dresden (DE); Thomas Kuehnel, Pirna (DE); Sebastian Bunk, Dresden (DE); Nicolas Schiller, Stolpen OT Helmsdorf (DE)

(73) Assignee: FRAUNHOFER-GESELLSCHAFT ZUR FOERDERUNG DER ANGEWANDTEN FORSCHUNG E.V., Muenchen (DE)

(21) Appl. No.: 13/980,245

(22) PCT Filed: Feb. 15, 2012
(86) PCT No.: PCT/EP2012/052624

§ 371 Date: Jul. 17, 2013

(30) Foreign Application Priority Data
Apr. 18, 2011 (DE) 10 2011 017 403.6

(51) Int. Cl. C23C 16/18; C23C 16/40; C23C 16/511; C23C 16/34

(52) U.S. Cl. CPC C23C 16/18; C23C 16/34; C23C 16/40; C23C 16/511
USPC 427/575; 427/578; 427/579

(57) ABSTRACT

The invention relates to a method for producing a transparent barrier layer system, wherein in a vacuum chamber at least two transparent barrier layers and a transparent intermediate layer disposed between the two barrier layers are deposited on a transparent plastic film, wherein for deposition of the barrier layers aluminium is vaporised and simultaneously at least one first reactive gas is introduced into the vacuum chamber and wherein for deposition of the intermediate layer aluminium is vaporised and simultaneously at least one second reactive gas is introduced into the vacuum chamber, and a silicon-containing layer is deposited as intermediate layer by means of a PECVD process.

The invention relates to a method for depositing a transparent layer system with a barrier effect against water vapor and oxygen.

### PRIOR ART

Electronically active materials, which are used in many different electronic assemblies, often have a high sensitivity to moisture and atmospheric oxygen. In order to protect these materials, it is known to encapsulate assemblies of this type. This occurs on the one hand by the direct deposition of a protective layer on the materials that are to be protected or by surrounding the assemblies using additional components. Thus, solar cells, for example, are often protected against moisture and other external influences by glass. In order to save weight and also achieve additional degrees of freedom with respect to the design, plastic films are also used for the encapsulation. Such plastic films must be coated for a sufficient protective effect. Therefore, at least one so-called permeation blocking layer (hereinafter also referred to as a barrier layer) is deposited on the plastic films.

Barrier layers oppose different permeating substances partially with a very different resistance. The permeation, under defined conditions, of oxygen (OTR) and water vapor (WVTR) through the substrates provided with the barrier layer is frequently used for the characterization of barrier layers (WVTR according to DIN 53122-2-A; OTR according to DIN 53380-3).

Because of the coating with a barrier layer, the permeation through a coated substrate is reduced compared to an uncoated substrate by a factor that can be in the single-digit range or many orders of magnitude. In addition to predefined barrier values, various other target parameters of a barrier layer are also often expected. An example hereof is optical, mechanical and technological-economical demands. Thus, barrier layers are often to be virtually completely transparent in the visible spectral range or beyond that. If barrier layers are used in layer systems, it is often advantageous if coating steps for applying individual parts of the layer system can be combined with one another.

To produce barrier layers, so-called PECVD methods (plasma enhanced chemical vapor deposition) are often used. These methods can be used when coating many different substrates for various layer materials. For example, it is known to deposit SiO₂ layers and Si₃N₄ layers at a thickness of 20 to 30 nm on 13 μm of PET substrates [A. S. da Silva Sobrinho et al., J. Vac. Sci. Technol. A 16(6), November/December 1998, p. 3190-3198]. At a working pressure of 10 Pa, permeation values of WVTR=0.3 g/m²d and OTR=0.5 cm³/m²d can be achieved in this manner.

When depositing SiOₓ for transparent barrier layers on PET substrates by means of PECVD, an oxygen barrier of OTR=0.7 cm³/m²d can be achieved [R. J. Nelson and H. Chatham, Society of Vacuum Coaters, 34th Annual Technical Conference Proceedings (1991) p. 113-117]. In another source, permeation values on the scale of WVTR=0.3 g/m²d and OTR=0.5 cm³/m²d are specified for this technology for transparent barrier layers on PET substrates [M. Izu, B. Dotter, S. R. Ovshinsky, Society of Vacuum Coaters, 36th Annual Technical Conference Proceedings (1993) p. 333-340].

Disadvantages of the known PECVD methods are, above all, that only relatively small barrier effects are achieved. This makes such barrier layers unappealing, in particular for the encapsulation of electronic products. A further disadvantage is the high working pressure that is necessary for the execution of such a method. If a coating step of this type is to be integrated into complex production sequences on vacuum equipment, a high expenditure for pressure decoupling measures possibly becomes necessary. A combination with other coating processes usually becomes uneconomical for this reason.

Furthermore, it is known to apply barrier layers by means of sputtering. Sputtered individual layers often exhibit better barrier properties than PECVD layers. For sputtered AlNO on PET, WVTR=0.2 g/m²d and OTR=1 cm³/m²d are stated for example as permeation values [Thin Solid Films 388 (2001) 78-86]. In addition, numerous other materials are known which are used for producing transparent barrier layers in particular by means of reactive sputtering. However, the layers produced in this manner also have barrier effects that are too small. An additional disadvantage of layers of this type is their low mechanical loadability. Damages which occur due to technologically unavoidable stresses during further processing or use usually lead to a clear deterioration of the barrier effect. This often renders sputtered individual layers unusable for barrier applications. A further disadvantage of sputtered layers is their high costs, which are caused by the low productivity of the sputtering process.

Furthermore, it is known to vapor deposit individual layers as barrier layers. Using such PVD methods, various materials can also be directly or reactively deposited on many different substrates. For barrier applications, for example, the reactive vapor coating of PET substrates with Al₂O₃ is known [Surface and Coatings Technology 125 (2000) 354-360]. Here, permeation values of WVTR=1 g/m²d and OTR=5 cm³/m²d are achieved. This barrier effect is likewise much too small to be able to use materials coated in this manner as barrier layers for electronic products. They are often mechanically even less loadable than sputtered individual layers. However, the very high coating rates that are achieved by vaporization processes are advantageous. These rates are typically greater than those achieved by sputtering by a factor of 100.

It is likewise known, when depositing barrier layers, to use magnetron plasmas for a plasma polymerization (EP 0 815 283 B1); [So Fujimaki, H. Kashiwase, Y. Kokaku, Vacuum 59 (2000) p. 657-664]. This concerns PECVD processes that are directly sustained by the plasma of a magnetron discharge. An example hereof is the use of a magnetron plasma for PECVD coating to deposit layers with a carbon framework, wherein CH₄ serves as a precursor. However, layers of this type also have a barrier effect that is merely insufficient for high demands.

Furthermore, it is known to apply barrier layers or barrier layer systems in multiple coating steps. One method from this class is the so-called PML (polymer multilayer) process (1999 Materials Research Society, p. 247-254); [J. D. Affinito, M. E. Gross, C. A. Coronado, G. L. Graff, E. N. Greenweil and P. M. Martin, Society of Vacuum Coaters, 39th Annual Technical Conference Proceedings (1996) p. 392-397].

In the PML process, a liquid acrylate film is applied to a substrate by means of a vaporizer, which film is cured using electron-beam technology or UV irradiation. This film itself does not have a particularly high barrier effect. Subsequently, a coating of the cured acrylate film occurs using an oxidic intermediate layer, to which an acrylate film is in turn applied. If needed, this procedure is repeated multiple times. The permeation values of a layer stack produced in this manner, that is, of a combination of individual oxidic barrier layers with acrylate layers as intermediate layers, is below the measuring limit of conventional permeation-measuring devices. Here, disadvantages occur above all in the necessary use of costly industrial manufacturing equipment. In addition, a liquid film first forms on the substrate, which film must be cured. This leads to an increased contamination of the equipment, which shortens service cycles. In coating processes of this type, the intermediate layer functioning as a barrier layer is usually produced by means of magnetron sputtering. Here, it is also disadvantageous that a comparatively slow process is resorted to due to the use of sputtering technology. Thus, very high product costs result which stem from the low productivity of the technologies used.

It is known that the mechanical stability of inorganic vaporized layers can be improved if an organic modification is performed during the vaporization. The installation of organic components thereby occurs in the inorganic matrix that forms during the layer growth. Because of the installation of these additional components in the inorganic matrix, an increase in the elasticity of the entire layer evidently results, which markedly reduces the risk of ruptures in the layer. In this context, a combination process that combines an electron-beam vaporization of SiOₓ with the admission of HMDSO (DE 195 48 160 C1) should be named representatively, as at least suitable for barrier applications. However, the low permeation rates necessary for electronic components cannot be achieved using layers produced in this manner.

Problem

The invention is therefore based on the technical problem of creating a method with which the disadvantages from the prior art are overcome. In particular, a transparent barrier layer system with a high blocking effect against oxygen and water vapor, as well as a high coating rate, is to be producible using the method.

The solution to the technical problem follows from the subject matters with the features of claim 1. Further advantageous embodiments follow from the dependent claims.

For a method according to the invention for producing a transparent barrier layer system, at least two transparent barrier layers are deposited on a transparent plastic film inside a vacuum chamber, between which barrier layers a transparent intermediate layer is also embedded. For the deposition of the barrier layers, aluminum is vaporized inside the vacuum chamber in a reactive process by admitting at least one additional reactive gas, such as oxygen or nitrogen for example, into the vacuum chamber simultaneously during the vaporization of the aluminum. As an intermediate layer, a layer containing silicon is embedded between the two barrier layers, which silicon-containing layer is deposited by means of a plasma-assisted CVD process. Processes of this type are also referred to as PECVD processes.

In particular, precursors containing silicon, such as HMDSO, HMDSN or TEOS, are suitable as source materials for the PECVD process. In this manner, an organically cross-linked intermediate layer containing silicon is produced which imparts to the emerging barrier compound a higher elasticity than a compound without this intermediate layer because of the organic cross-liking in the intermediate layer.

Hollow cathodes or even magnetrons can be used to produce a plasma for the PECVD process.

In an embodiment of the invention, a magnetron is used as a plasma-producing device, from the target of which magnetron particles are sputtered off which are involved in the layer construction of the intermediate layer. At this juncture, it should be explicitly mentioned that the sputtering off of particles of a target belonging to the magnetron is not material to the invention. A magnetron in the PECVD process of a method according to the invention is primarily used to produce a plasma that splits source materials admitted into the vacuum chamber and induces the chemical layer deposition.

During the PECVD process, additional reactive gases, such as oxygen and/or nitrogen for example, can also be admitted into the vacuum chamber.

A barrier layer system deposited using the method according to the invention is furthermore characterized by a high blocking effect against water vapor and oxygen, wherein the layer system can also still be deposited with the high coating rates known for the vaporization and for PECVD processes. Because of these properties, barrier layer systems deposited according to the invention are, for example, suitable for the encapsulation of components in the production of solar cells or for the encapsulation of OLEDs and other electronically active materials.

The high blocking effect of the layer system deposited according to the invention against water vapor and oxygen is mainly accounted for in that an organically cross-linked layer containing silicon causes a growth stop of layer defects of a barrier layer deposited thereunder by reactive aluminum vaporization. It is known that, once they have occurred, layer defects that arise during the reactive vaporization of aluminum often grow with the layer growth through the remaining layer thickness. The organically cross-linked, silicon-containing intermediate layer deposited between the barrier layers in the method according to the invention is able to cover the layer defects of the barrier layer lying thereunder, such that these defects are not extended during the growing of the second barrier layer lying above the intermediate layer. Thus, a high barrier effect or blocking effect against water vapor and oxygen can be achieved using a layer system deposited according to the invention. The blocking effect against water vapor and oxygen can, up to a certain degree, be still further increased if barrier layer and intermediate layer are alternatingly deposited after one another multiple times.

For the vaporization of the aluminum during the deposition of a barrier layer, boat vaporizers or electron-beam vaporizers known for the vaporization can be used. Additionally, the deposition of barrier layers can also be assisted by a plasma that penetrates the space between aluminum vaporizer and a plastic film substrate that is to be coated. Here, in particular, hollow cathode plasmas or microwave plasmas are suitable.

The deposition of barrier layer and intermediate layer can either occur in one vacuum chamber or in two separate vacuum chambers.

### EXEMPLARY EMBODIMENT

The invention is explained in greater detail below by means of an exemplary embodiment. For a 650-mm-wide and 75-μm-thick plastic film of the material PET, the blocking effect against water vapor is to be increased. For this purpose, the plastic film is, in a first coating step, coated with an aluminum oxide layer embodied as a barrier layer in a first vacuum chamber by vaporizing aluminum in the vacuum chamber and simultaneously also admitting oxygen into the vacuum chamber at 14.2 slm.

To vaporize the aluminum, eight known boat vaporizers are used which are arranged below the plastic film that is to be coated distributed at a uniform distance across the width of the plastic film. The vaporization of the aluminum occurs at a vaporization rate of 2 g/min for each boat vaporizer, wherein the plastic film is moved past the boat vaporizer at a belt speed of 30 m/min. The aluminum oxide layer embodied as a barrier layer is deposited in a plasma-assisted manner. Four hollow cathodes, which are likewise arranged distributed at a uniform distance across the width of the plastic film, produce a plasma that penetrates on the one side the space between the boat vaporizers and on the other side the plastic film that is to be coated. The four hollow cathodes are thereby fed by an electric current of respectively 270 A. For the parameters indicated, an aluminum oxide layer with a layer thickness of 90 nm is deposited on the plastic film.

In a second coating step, an intermediate layer is applied to the barrier layer at an identical belt speed. For this purpose, the plastic film substrate provided with the barrier layer is guided through a second vacuum chamber, into which the precursor HMDSO containing silicon flows at 175 sscm and into which the reactive gas oxygen flows at 130 sscm. The plasma of a magnetron with an output of 7.5 kW in the second vacuum chamber splits the precursor, activates the split components and thus causes these components to undergo a chemical layer deposition on the plastic film provided with the barrier layer. As a result of this layer-depositing process, an organically cross-linked layer containing silicon grows across the barrier layer. As previously mentioned, the plasma in this PECVD process is produced by means of a magnetron. A magnetron is typically also used in order to produce particles for the deposition of a layer. During deposition of this intermediate layer according to the method according to the invention, however, no sputter erosion from the magnetron target and therefore no contribution to the provision of particles for the layer construction is necessary. In this method step, the magnetron merely serves to produce a plasma.

After this coating step, a barrier layer and an intermediate layer are deposited on the PET film. The respective deposition of a barrier layer and an intermediate layer is hereinafter referred to as a dyad. In subsequent coating steps, additional barrier layers and intermediate layers were respectively applied alternatingly to the plastic film with the above-mentioned parameters until 5 dyads altogether were completed. After each dyad, the value for the permeation of water vapor was measured on the then respectively present compound of plastic layer, barrier layers and intermediate layers, which are illustrated in Tab. 1.

TABLE 1

| Number of dyads | WVTR [g/m²/d] |
|---|---|
| 1 | 0.5 |
| 2 | 0.2 |
| 3 | 0.09 |
| 4 | 0.04 |
| 5 | 0.009 |

As can be seen from Tab. 1, the blocking effect against water vapor was able to be improved from dyad to dyad, which is a sign that the intermediate layers resulting from the method according to the invention interrupt effectively the defect growth from a barrier layer to the barrier layer deposited thereabove.

At this juncture, it should be mentioned that the previously indicated values of physical sizes of coating parameters are only provided by way of example and do not limit the method according to the invention.

1. Method for producing a transparent barrier layer system, wherein at least two transparent barrier layers and one transparent intermediate layer arranged between the two barrier layers are deposited on a transparent plastic film in at least one vacuum chamber, characterized in that aluminum is vaporized for the deposition of the barrier layers and at least one first reactive gas is simultaneously admitted into the vacuum chamber, and in that a layer containing silicon is deposited as an intermediate layer by means of a PECVD process.

2. Method according to claim 1, characterized in that the barrier layer and the second layer are alternatingly deposited multiple times.

3. Method according to claim 1, characterized in that oxygen and/or nitrogen is used as a first reactive gas.

4. Method according to claim 1, characterized in that the deposition of the barrier layer occurs in the vacuum chamber in the presence of a plasma.

5. Method according to claim 4, characterized in that a hollow cathode plasma or a microwave plasma is used as a plasma.

6. Method according to claim 1, characterized in that a magnetron plasma or a hollow cathode plasma is used for the PECVD process.

7. Method according to claim 1, characterized in that a precursor containing silicon is admitted into the vacuum chamber as a source material for the PECVD process.

8. Method according to claim 7, characterized in that HMDSO, HMDSN or TEOS is used as a precursor.

9. Method according to claim 1, characterized in that a second reactive gas is also additionally admitted into the vacuum chamber during the PECVD process.

10. Method according to claim 9, characterized in that oxygen or/and nitrogen is used as a second reactive gas.
